(19) United States
(12) Patent Application Publication
(10) Pub. No.: US 2006/0267003 A1
(43) Pub. Date: Nov. 30, 2006

(54) Organic thin film transistor (OTFT), its method of fabrication, and flat panel display including OTFT

(76) Inventors: Min-Chul Suh, Suwon-si (KR); Yong-Woo Park, Suwon-si (KR); Yeon-Gon Mo, Suwon-si (KR)

Correspondence Address: Robert E. Bushnell, Suite 300, 1522 K Street, N.W., Washington, DC, 20005, US

(21) Appl. No.: 11/417,046

(22) Filed: May 4, 2006

(30) Foreign Application Priority Data
May 24, 2005 (KR) 2005-43701

(51) Int. Cl. H01L 29/08

(52) U.S. Cl. 257/40; 438/99

(57) ABSTRACT

An Organic Thin Film Transistor (OTFT) having improved characteristics due to surface-treating of a portion of a substrate corresponding to a channel region using a fluoride-based gas to stabilize the channel region, a method of fabricating such an OTFT, and an organic Electroluminescent (EL) display including such an OTFT includes: treating a predetermined portion of a surface of a substrate; forming a source electrode and a drain electrode on portions of the substrate which have not been surface-treated; forming a semiconductor layer to contact the surface-treated portion of the substrate; forming a gate insulating layer on the substrate; and forming a gate on the gate insulating layer. The substrate is plasma surface-treated using a fluoride-based gas such as CF₄ or C₃F₈.

### CLAIM OR PRIORITY

This application makes reference to, incorporates the same herein, and claims all benefits accruing under 35 U.S.C.§119 from an application for OTFT AND FABRICATION METHOD THEREOF AND FLAT PANEL DISPLAY WITH OTFT earlier filed in the Korean Intellectual Property Office on the 24^{th} of May 2005 and there duly assigned Serial No. 10-2005-0043701.

### BACKGROUND OF THE INVENTION

1. Field of the Invention

The present invention relates to an Organic Thin Film Transistor (OTFT), and more particularly, to an OTFT that has improved characteristics due to stabilization of its channel layer by processing a surface of its substrate using a fluoride-based gas, a method of fabricating such an OTFT, and an organic electroluminescent (EL) flat panel display including the OTFT.

2. Description of the Related Art

Flexible organic electroluminescent (EL) displays generally include flexible substrates such as plastic substrates. Plastic substrates are not heat-resistant, and thus, flexible organic EL displays must be fabricated at a low temperature.

Organic Thin Film Transistors (OTFTs) that can operate at a low temperature can be used as driving devices in flexible organic EL displays. OTFTs have been actively researched as possible driving devices in next generation displays.

OTFTs use an organic layer as a semiconductor layer instead of using a silicon layer. OTFTs can be classified as low polymer OTFTs using polymers such as oligothiophene and pentacene and high polymer OTFTs using polymers such as polythiophene.

In an OTFT, in which a semiconductor layer includes organic material, when a surface of a substrate is polarized, a channel layer of the organic semiconductor layer contacting the surface of the substrate is unstable, and thus, characteristics of the OTFT are degraded.

### SUMMARY OF THE INVENTION

The present invention provides an Organic Thin Film Transistor (OTFT) having a stabilized channel region due to processing a surface of its' substrate using a fluoride-based gas, and a method of fabricating such an OTFT.

The present invention also provides an organic electroluminescent (EL) display apparatus including such an OTFT having a stabilized channel layer.

According to one aspect of the present invention, a Thin Film Transistor (TFT) is provided including: a substrate including a first region contacting a channel region, and a second region not contacting the channel region, the first region and the second region having different surface properties from each other; a source electrode and a drain electrode arranged on the second region; a semiconductor layer including the channel region contacting the first region of the substrate; a gate arranged on the substrate; and a gate insulating layer arranged between the source and drain electrodes and the gate.

The semiconductor layer preferably includes an organic semiconductor material.

The first region of the substrate preferably includes a plasma-treated portion of the substrate. A surface of the first region of the substrate is plasma-treated using a fluoride-based gas including at least one of CF₄ or C₃F₈.

The semiconductor layer preferably includes the channel region having a surface modified by contacting the first region of the substrate.

The channel region of the semiconductor layer is preferably modified to a depth in a range of tens˜hundreds of Å from a surface of the channel region contacting the first region of the substrate.

According to another aspect of the present invention, a Thin Film Transistor (TFT) is provided including: a gate arranged on a substrate; a gate insulating layer arranged on the substrate, and including a first region contacting a channel region and a second region not contacting the channel region, the first region and the second region having different surface properties from each other; a source electrode and a drain electrode arranged on the second region of the gate insulating layer; and a semiconductor layer including the channel region contacting the first region of the gate insulating layer.

The semiconductor layer preferably includes an organic semiconductor material.

The first region of the gate insulating layer preferably includes a plasma-treated portion of the gate insulating layer.

A surface of the first region of the gate insulating layer is preferably plasma-treated using a fluoride-based gas comprising at least one of CF₄ or C₃F₈.

The semiconductor layer preferably includes the channel region having a surface modified by contacting the first region of the gate insulating layer. The channel region of the semiconductor layer is modified to a depth in a range of tens˜hundreds Å from a surface of the channel region contacting the first region of the gate insulating layer.

According to still another aspect of the present invention, a method of fabricating a Thin Film Transistor (TFT) is provided including: treating a predetermined portion of a surface of a substrate; forming a source electrode and a drain electrode on portions of the substrate which have not been surface-treated; forming a semiconductor layer to contact the surface-treated portion of the substrate; forming a gate insulating layer on the substrate; and forming a gate on the gate insulating layer.

The surface-treated portion of the substrate is preferably treated by a plasma using a fluoride-based gas comprising at least one of CF₄ or C₃F₈.

The semiconductor layer preferably includes a channel region, a surface of which is modified, contacting the plasma surface-treated portion of the substrate, and modifying the channel region to a depth in a range of tens of ˜hundreds of Å from a surface of the channel region contacting the substrate.

According to yet another aspect of the present invention, a flat panel display including a Thin Film Transistor (TFT) fabricated by a method is provided, the method including: treating a predetermined portion of a surface of a substrate; forming a source electrode and a drain electrode on portions of the substrate which have not been surface-treated; forming a semiconductor layer to contact the surface-treated portion of the substrate; forming a gate insulating layer on the substrate; and forming a gate on the gate insulating layer.

According to a further aspect of the present invention, a method of fabricating a Thin Film Transistor (TFT) is provided, the method including: forming a gate on a substrate; forming a gate insulating layer on the substrate; treating a predetermined portion of a surface of the gate insulating layer; forming a source electrode and a drain electrode on portions of the gate insulating layer which have not been treated; and forming a semiconductor layer contacting the surface-treated portion of the gate insulating layer.

The surface-treated portion of the substrate is preferably treated by a plasma using a fluoride-based gas comprising at least one of CF₄ or C₃F₈.

The semiconductor layer preferably includes a channel region, a surface of which is modified, contacting the plasma surface-treated portion of the gate insulating layer, and modifying the channel region to a depth in a range of tens of ˜hundreds of Å from a surface of the channel region contacting the gate insulating layer.

According to still another aspect of the present invention, a flat panel display including a Thin Film Transistor (TFT) fabricated by a method is provided, the method including: forming a gate on a substrate; forming a gate insulating layer on the substrate; treating a predetermined portion of a surface of the gate insulating layer; forming a source electrode and a drain electrode on portions of the gate insulating layer which have not been treated; and forming a semiconductor layer contacting the surface-treated portion of the gate insulating layer.

### BRIEF DESCRIPTION OF THE DRAWINGS

A more complete appreciation of the present invention and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a cross-sectional view of an Organic Thin Film Transistor (OTFT) having a top gate structure according to an embodiment of the present invention;

FIGS. 2A through 2C are cross-sectional views of a method of fabricating the OTFT of FIG. 1 according to another embodiment of the present invention;

FIG. 3 is a cross-sectional view of an OTFT having a bottom gate structure according to another embodiment of the present invention;

FIGS. 4A through 4C are cross-sectional views of a method of fabricating the OTFT of FIG. 3 according to another embodiment of the present invention;

FIG. 5 is a cross-sectional view of an organic electroluminescent (EL) display apparatus according to an embodiment of the present invention; and

FIG. 6 is a cross-sectional view of an organic EL display apparatus according to another embodiment of the present invention.

### DETAILED DESCRIPTION OF THE INVENTION

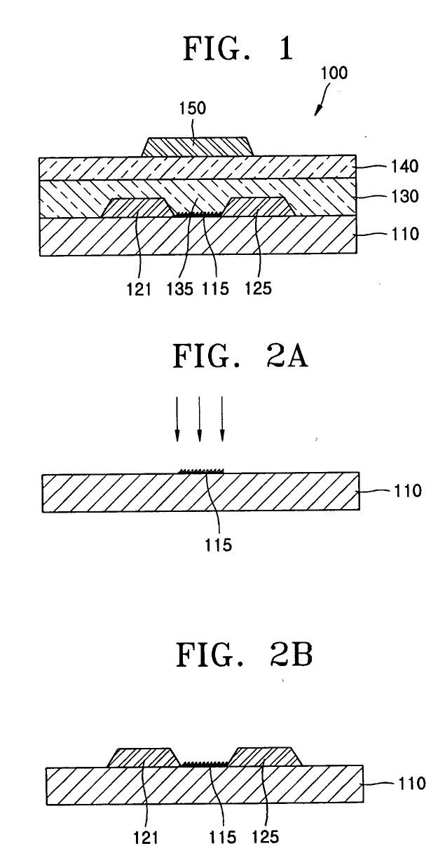

FIG. 1 is a cross-sectional view of an Organic Thin Film Transistor (OTFT) according to an embodiment of the present invention. The OTFT 100 of FIG. 1 has a top gate structure.

Referring to FIG. 1, the OTFT 100 includes a substrate 110, on which a portion 115 s between a source electrode 121 and a drain electrode 125, that is, a portion contacting a channel region 135 of a semiconductor layer 130 is surface-treated. The surface-treated portion 115 of the substrate 110 is treated by plasma using a fluoride-based gas such as CF₄ or C₃F₈.

Fluoride atoms (F) prevent the substrate from being polarized and stabilize the surface of the substrate, and thus, the portion 115 is formed. Therefore, the surface-treated portion 115 of the substrate 110 has a stronger hydrophobic property than a remaining portion of the substrate 110.

The substrate 110 can be a glass substrate, a plastic substrate, or a metal substrate. The metal substrate can be a Steel Use Stainless (SUS). The plastic substrate can be a plastic film selected from a group consisting of Polyethersulphone (PES), Polyacrylate (PAR), Polyetherimide (PEI), Polyethylenenaphthalate (PEN), Polyethyleneterephthalate (PET), Phlyphenylene Sulfide (PPS), Polyallylate, Polyimide, Polycarbonate (PC), Cellulose Tri-acetate (TAC), and Cellulose Acetate Propinonate (CAP).

The source electrode 121 and the drain electrode 125 are formed on the portion of the substrate 110 which is not surface-treated. The semiconductor layer 130 including the channel region 135 between the source electrode 121 and the drain electrode 125 is formed on the substrate 110. The semiconductor layer 130 contacts the source electrode 121 and the drain electrode 125, and the channel region 135 between the source electrode 121 and the drain electrode 125 contacts the surface-treated portion 115 of the substrate 110.

Therefore, since the channel region 135 of the semiconductor layer 130 contacts the surface-treated portion 115 of the substrate 110, an interlayer between the channel region 135 and the substrate 110 can be stabilized. The hydrophobic fluoride atoms F are combined with the organic material of the semiconductor layer 130 through the plasma treatment using the fluoride-based gas, and thus, the surface of the substrate 110 is not polarized and the surface is stabilized.

That is, a direct chemical reaction (substitution reaction) is accelerated under the fluoride-based plasma atmosphere, and thus, a surface property of the organic thin film is changed. Therefore, chemical and physical properties of the surface of the semiconductor layer 130 are changed, and an interfacial property between the substrate 110 and the channel region of the semiconductor layer 130 can be improved.

A surface of the channel region 135 of the semiconductor layer 130 contacting the substrate 110 is only modified by the plasma treatment, and the remaining bulk region is unchanged. A depth of the modified portion of the channel region 135 is approximately tens˜hundreds Å from the surface of the channel region contacting the surface-treated portion 115 of the substrate 110. The term “modification” means that the surface property of channel region 135 is changed into the hydrophobic property by the plasma treatment. The surface treatment of the substrate 110 suppresses polarization of the surface of the substrate 110. Therefore, the surface of the channel region 135 which contacts with the substrate, can be prevented from being polarized by the modification of the surface property of the substrate.

The semiconductor layer 130 can be an organic semiconductor layer, formed of a material selected from a group consisting of pentacene, tetracene, anthracene, naphthalene, alpha-6-thiophene, perylene and derivatives thereof, rubrene and derivatives thereof, coronene and derivatives thereof, perylene tetracarboxylic diimide and derivatives thereof, perylene tetracarboxylic dianhydride and derivatives thereof, polythiophene and derivatives thereof, polyparaperylenevinylene and derivatives thereof, polyflorene and derivatives thereof, polythiophenevinylene and derivatives thereof, polyparaphenylene and derivatives thereof, polythiophene-heteroring aromatic copolymer and derivatives thereof, oligophthalene and derivatives thereof, alpha-5-thiophene oligothiophene and derivatives thereof, phthalocyanine containing metal or not containing metal and derivatives thereof, pyromellitic dianhydride and derivatives thereof, pyromellitic diimide and derivatives thereof, perylenetetracarboxylic acid dianhydride and derivatives thereof, naphthalene tetracarboxylic acid diimide and derivatives thereof, and naphthalene tetracarboxylic acid dianhydride and derivatives thereof.

The OTFT 100 includes a gate insulating layer 140 formed on the semiconductor layer 130, and a gate 150 formed on the gate insulating layer 140 to correspond to the channel region 135 of the semiconductor layer 130. Although it is not shown in the drawings, a buffer layer can be further disposed between the substrate 110 and the source and drain electrodes 121 and 125.

The gate insulating layer 140 can be an inorganic insulating layer, an organic insulating layer, or an inorganic-organic hybrid layer. The inorganic insulating layer used as the insulating layer 140 can be a nitride layer or an oxide layer, and the organic insulating layer can be selected from a group consisting of Benzocyclobutene (BCB), Polyimide, Parylene, and Polyvinylphenol (PVP).

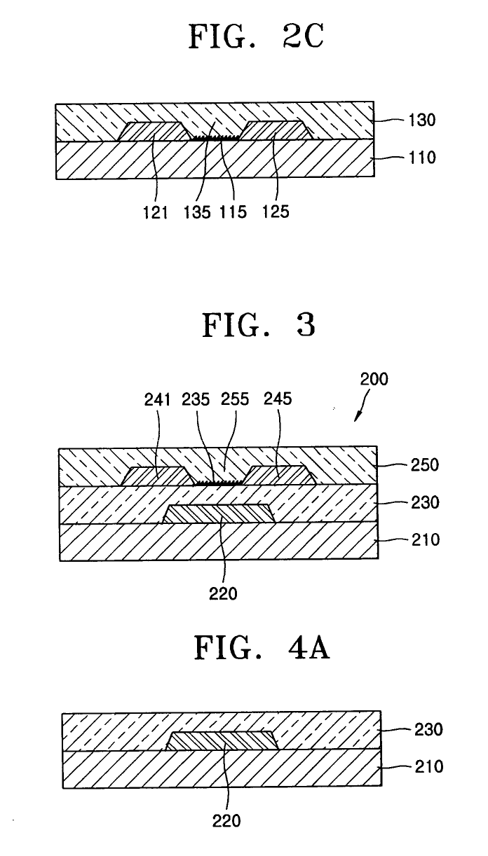

FIGS. 2A through 2C are cross-sectional views of a method of fabricating the OTFT in FIG. 1 according to an embodiment of the present invention.

Referring to FIG. 2A, a predetermined portion 115 of the substrate 110 is treated by a plasma to prevent the substrate 110 from being polarized. The plasma treatment process is performed using a fluoride-based gas such as CF₄ or C₃F₈. The surface-treated portion 115 of the substrate 110 contacts a channel region of a semiconductor layer that is formed in subsequent processes. The portion 115 has a stronger hydrophobic property than the remaining portion of the substrate 110 due to the fluoride atoms F.

Referring to FIG. 2B, the source electrode 121 and the drain electrode 125 are formed on portions of the substrate 110, which are not treated by the plasma. Referring to FIG. 2C, the semiconductor layer 130 is formed on the substrate 110. The semiconductor layer 130 includes an organic semiconductor material. The channel region 135 of the semiconductor layer 130 contacts the surface-treated portion 115 of the substrate 110. The channel region 135 of the semiconductor layer 130 is modified to a depth of tens˜hundreds A where it contacts the portion 115 of the substrate 110, and the remaining bulk portion of the channel region 135 is unchanged.

In addition, the gate insulating layer 140 is formed on the substrate, and the gate electrode 150 is formed on the gate insulating layer 140 to correspond to the channel region 135 of the semiconductor layer 130. Then, the OTFT of FIG. 1 is obtained.

FIG. 3 is a cross-sectional view of an OTFT according to another embodiment of the present invention. The OTFT 200 of FIG. 3 has a bottom gate structure.

Referring to FIG. 3, the OTFT 200 includes a gate 220 and a gate insulating layer 230 formed on a substrate 210. A portion 235 of the gate insulating layer 230 disposed between a source electrode and a drain electrode, that is, a portion that contacts a channel region 235 of a semiconductor layer 250 is surface-treated. The portion 235 of the gate insulating layer is surface-treated by a plasma using a fluoride-based gas such as CF₄ or C₃F₈.

The surface-treated portion 235 of the gate insulating layer 230 has a different surface property from that of the remaining portion of the gate insulating layer 230. That is, the surface-treated portion 235 of the gate insulating layer 230 has a stronger hydrophobic property than the remaining portion of the gate insulating layer 230. The surface-treated portion 235 of the gate insulating layer 230 prevents the gate insulating layer from being polarized using fluoride atoms F, and stabilizes the surface of the gate insulating layer 230.

The substrate 210 can be a glass substrate, a plastic substrate, or a metal substrate. The gate insulating layer 230 can be an inorganic insulating layer, an organic insulating layer, or an inorganic-organic hybrid layer. The inorganic insulating layer used as the insulating layer 230 can be a nitride layer or an oxide layer, and the organic insulating layer can be selected from a group consisting of Benzocyclobutene (BCB), Polyimide, Parylene, and Polyvinylphenol (PVP).

A source electrode 241 and a drain electrode 245 are formed on portions of the gate insulating layer 230 which are not surface-treated. The semiconductor layer 250 including the channel region 255 between the source electrode 241 and the drain electrode 245 is formed on the gate insulating layer 230. The semiconductor layer 250 includes an organic semiconductor material.

The semiconductor layer 250 contacts the source electrode 241 and the drain electrode 245, and the channel region 255 between the source electrode 241 and the drain electrode 245 contacts the surface-treated portion 235 of the gate insulating layer 230. Therefore, the channel region 255 of the semiconductor layer 250 contacts the surface-treated portion 235 of the gate insulating layer 230, and thus, an interlayer between the channel region 255 and the gate insulating layer 230 can be stabilized.

Through the surface-treatment using the fluoride-based gas, the fluoride atoms F having hydrophobic property are combined with the organic material of the semiconductor layer 250 to prevent the gate insulating layer 230 from being polarized, and thus, a surface of the gate insulating layer 230 contacting the channel region 255 of the semiconductor layer 250 can be stabilized. Therefore, chemical and physical properties of the surface of the semiconductor layer 250 are changed, and an interfacial property between the gate insulating layer 230 and the channel region 255 of the semiconductor layer 250 can be improved.

The surface of the channel region 255 contacting the surface-treated portion 235 of the gate insulating layer 230 is only modified through the surface-treatment by the plasma, and the remaining bulk portion of the channel region 255 is unchanged. The channel region 255 of the semiconductor layer 250 contacting the surface treated portion 235 of the gate insulating layer 230 is modified to a depth of tens˜hundreds Å.

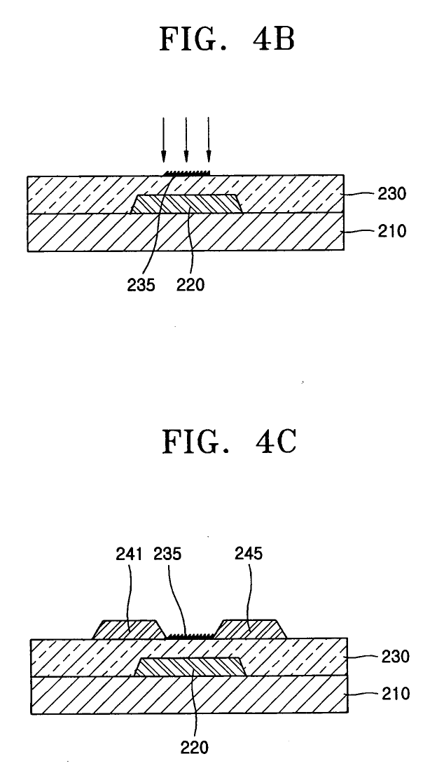

FIGS. 4A through 4C are cross-sectional views of a method of fabricating the OTFT of FIG. 3 having the bottom gate structure according to another embodiment of the present invention.

Referring to FIG. 4A, a gate 220 is formed on a predetermined portion of the substrate 210, and the gate insulating layer 230 is formed on the substrate 210 on which the gate 220 is formed. Referring to FIG. 4B, a predetermined portion 235 of the gate insulating layer 230 is treated by a plasma in order to prevent a surface of the gate insulating layer 230 from being polarized and to stabilize the surface.

The surface-treatment by plasma is performed using a fluoride-based gas such as CF₄ or C₃F₈. The surface-treated portion 235 of the gate insulating layer 230 contacts a channel region of a semiconductor layer that is formed in subsequent processes. The surface-treated portion 235 contacting the channel region of the semiconductor layer has a stronger hydrophobic property than the remaining portion of the gate insulating layer 230 due to the fluoride atoms F.

Referring to FIG. 4C, the source electrode 241 and the drain electrode 245 are formed on portions of the gate insulating layer 230, which are not treated. In addition, the semiconductor layer 250 is formed on the gate insulating layer 230, and thus, the OTFT 200 of FIG. 3 is obtained.

The semiconductor layer 250 includes an organic semiconductor material. The channel region 255 of the semiconductor layer 250 contacts the surface-treated portion 235 of the gate insulating layer 230. The channel region 255 of the semiconductor layer 250 contacting the surface treated portion 235 of the gate insulating layer 230 is modified to a depth of tens˜hundreds Å.

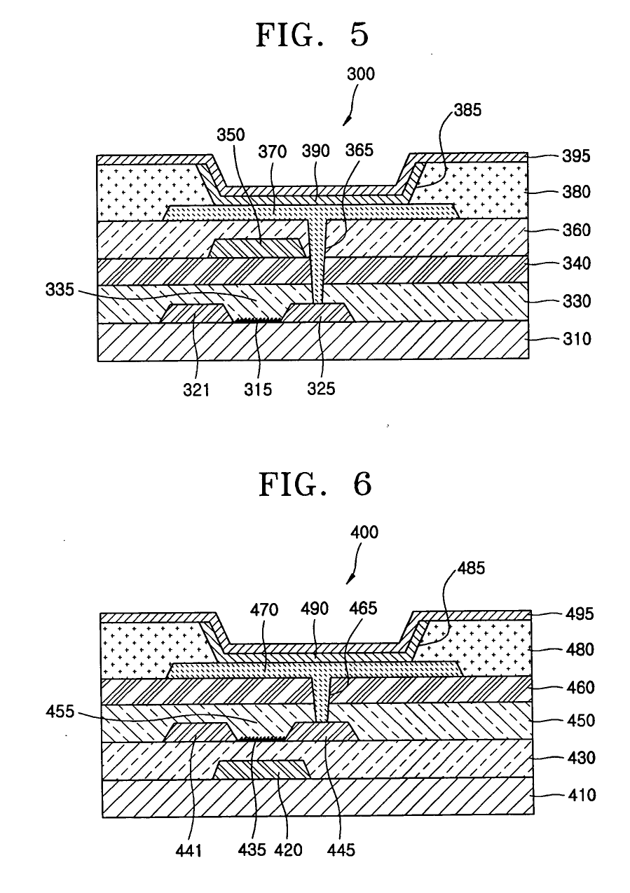

FIG. 5 is a cross-sectional view of an organic EL display including a top-gate Thin Film Transistor (TFT) according to another embodiment of the present invention. That is, FIG. 5 is an organic light emission device and an OTFT for driving the organic light emission device in an organic EL display 300.

Referring to FIG. 5, OTFT including a source electrode 321, a drain electrode 325, a semiconductor layer 330, and a gate 350 is formed. The source electrode 321 and the drain electrode 325 are formed on the substrate 310, and the semiconductor layer 330 is formed so as to contact the substrate 310 between the source electrode 321 and the drain electrode 325.

The semiconductor layer 330 includes an organic semiconductor material, and includes a channel region 335 between the source electrode 321 and the drain electrode 325. A portion 315 of the substrate 310 contacting the channel region 335 of the semiconductor layer 330 is treated by a plasma using the fluoride-based gas to modify the surface property of the channel region 335 of the semiconductor layer 330.

The gate insulating layer 340 is formed on the semiconductor layer 330, and the gate 350 is formed on the gate insulating layer 340 to correspond to the channel region 335 of the semiconductor layer 330. In addition, a protective layer 360 is formed on the gate insulating layer 340.

An organic light emission device including a lower electrode 370 connected to the drain electrode 325 through a via hole 365 in the protective layer 360, an organic layer 390, and an upper electrode 395 is formed. The lower electrode 370 is used as a pixel electrode, and is exposed by an opening 385 of a pixel separation layer 380.

The lower electrode 370 operates as an anode and the upper electrode 395 operates as a cathode. However, the lower electrode 370 can operate as the cathode and the upper electrode 395 can operate as the anode. The organic layer 390 can be one or more organic layers selected from a hole injection layer, a hole transport layer, a light emission layer, an electron 8 transport layer, an electron injection layer, and an electron restriction layer.

FIG. 6 is a cross-sectional view of an organic EL display apparatus including a bottom-gate TFT according to another embodiment of the present invention. That is, FIG. 6 is an organic light emission device and an OTFT for driving the organic light emission device in the organic EL display 400.

Referring to FIG. 6, an OTFT including a gate 420, a semiconductor layer 450, a source electrode 441, and a drain electrode 445 on a substrate 410 is formed. The gate 420 is formed on the substrate 410, and a gate insulating layer 430 is formed between the gate 420 and the semiconductor layer 450.

The semiconductor layer 450 includes an organic semiconductor material, and a channel region 455 to correspond to the gate 420. A portion 435 of the gate insulating layer 430, which contacts the channel region 455 of the semiconductor layer 450, is treated using a fluoride-based gas to modify a surface property of the channel region 455 of the semiconductor layer 450.

A protective layer 460 is formed on the semiconductor layer 450. An organic light emission device including a lower electrode 470 connected to the drain electrode 445 of the OTFT through a via hole 465 in the protective layer 460, an organic layer 490, and an upper electrode 495 is formed on the protective layer 460. The lower electrode 470 operates as a pixel electrode, and is exposed by an opening 485 of a pixel separation layer 480.

The lower electrode 470 operates as an anode and the upper electrode 495 operates as a cathode. However, the lower electrode 470 can operate as the cathode and the upper electrode 495 can operate as the anode. The organic layer 490 can be one or more organic layers selected from a hole injection layer, a hole transport layer, a light emission layer, an electron transport layer, an electron injection layer, and an electron restriction layer.

The OTFT and the organic EL display including the OTFT according to the present invention are not limited to the embodiments illustrated in the drawings, and can be applied to various OTFTs and organic EL displays.

In the present invention, the OTFT is used as a driving device in the organic EL display. However, an OTFT having the improved surface property of the present invention can be applied to flat panel displays such as Liquid Crystal Displays (LCDs) using the OTFT as the driving device.

According to the present invention, the organic semiconductor layer is not patterned and contacts the source/drain electrodes. However, the present invention can be applied to an OTFT having a patterned organic semiconductor layer.

According to the OTFT and the method of fabricating the OTFT of the present invention, the surface of the substrate contacting the channel region of the semiconductor layer is treated using a fluoride-based gas, and thus, a surface property of the channel region on the organic semiconductor layer can be modified and the properties of the OTFT can be improved.

While the present invention has been particularly shown and described with reference to exemplary embodiments thereof, it will be understood by those of ordinary skill in the art that various modifications in form and detail can be made therein without departing from the spirit and scope of the present invention as defined by the following claims.

What is claimed is:

1. A Thin Film Transistor (TFT), comprising:
a substrate including a first region contacting a channel region, and a second region not contacting the channel region, wherein the first region and the second region have different surface properties from each other;
a source electrode and a drain electrode arranged on the second region;
a semiconductor layer including the channel region contacting the first region of the substrate;
a gate arranged on the substrate; and
a gate insulating layer arranged between the source and drain electrodes and the gate.

2. The TFT of claim 1, wherein the semiconductor layer comprises an organic semiconductor material.

3. The TFT of claim 1, wherein the first region of the substrate comprises a plasma-treated portion of the substrate.

4. The TFT of claim 3, wherein a surface of the first region of the substrate is plasma-treated using a fluoride-based gas comprising at least one of CF₄ or C₃F₈.

5. The TFT of claim 3, wherein the semiconductor layer comprises the channel region having a surface modified by contacting the first region of the substrate.

6. The TFT of claim 5, wherein the channel region of the semiconductor layer is modified to a depth in a range of tens˜hundreds of Å from a surface of the channel region contacting the first region of the substrate.

7. A Thin Film Transistor (TFT), comprising:
a gate arranged on a substrate;
a gate insulating layer arranged on the substrate, and including a first region contacting a channel region and a second region not contacting the channel region, wherein the first region and the second region have different surface properties from each other;
a source electrode and a drain electrode arranged on the second region of the gate insulating layer; and
a semiconductor layer including the channel region contacting the first region of the gate insulating layer.

8. The TFT of claim 7, wherein the semiconductor layer comprises an organic semiconductor material.

9. The TFT of claim 8, wherein the first region of the gate insulating layer comprises a plasma-treated portion of the gate insulating layer.

10. The TFT of claim 9, wherein a surface of the first region of the gate insulating layer is plasma-treated using a fluoride-based gas comprising at least one of CF₄ or C₃F₈.

11. The TFT of claim 9, wherein the semiconductor layer includes the channel region having a surface modified by contacting the first region of the gate insulating layer.

12. The TFT of claim 11, wherein the channel region of the semiconductor layer is modified to a depth in a range of tens˜hundreds Å from a surface of the channel region contacting the first region of the gate insulating layer.

13. A method of fabricating a Thin Film Transistor (TFT), comprising:
treating a predetermined portion of a surface of a substrate;
forming a source electrode and a drain electrode on portions of the substrate which have not been surface-treated;
forming a semiconductor layer to contact the surface-treated portion of the substrate;
forming a gate insulating layer on the substrate; and
forming a gate on the gate insulating layer.

14. The method of claim 13, wherein the surface-treated portion of the substrate is treated by a plasma using a fluoride-based gas comprising at least one of CF₄ or C₃F₈.

15. The method of claim 13, wherein the semiconductor layer includes a channel region, a surface of which is modified, contacting the plasma surface-treated portion of the substrate, and modifying the channel region to a depth in a range of tens of ˜hundreds of Å from a surface of the channel region contacting the substrate.

16. A flat panel display including a Thin Film Transistor (TFT) fabricated by a method, comprising:
treating a predetermined portion of a surface of a substrate;
forming a source electrode and a drain electrode on portions of the substrate which have not been surface-treated;
forming a semiconductor layer to contact the surface-treated portion of the substrate;
forming a gate insulating layer on the substrate; and
forming a gate on the gate insulating layer.

17. A method of fabricating a Thin Film Transistor (TFT), comprising:
forming a gate on a substrate;
forming a gate insulating layer on the substrate;
treating a predetermined portion of a surface of the gate insulating layer;
forming a source electrode and a drain electrode on portions of the gate insulating layer which have not been treated; and
forming a semiconductor layer contacting the surface-treated portion of the gate insulating layer.

18. The method of claim 17, wherein the surface-treated portion of the substrate is treated by a plasma using a fluoride-based gas comprising at least one of CF₄ or C₃F₈.

19. The method of claim 18, wherein the semiconductor layer includes a channel region, a surface of which is modified, contacting the plasma surface-treated portion of the gate insulating layer, and modifying the channel region to a depth in a range of tens of ˜hundreds of Å from a surface of the channel region contacting the gate insulating layer.

20. A flat panel display including a Thin Film Transistor (TFT) fabricated by a method, comprising:
forming a gate on a substrate;
forming a gate insulating layer on the substrate;
treating a predetermined portion of a surface of the gate insulating layer;
forming a source electrode and a drain electrode on portions of the gate insulating layer which have not been treated; and
forming a semiconductor layer contacting the surface-treated portion of the gate insulating layer.
